(19) United States
(12) Patent Application Publication
(10) Pub. No.: US 2007/0070789 A1
(43) Pub. Date: Mar. 29, 2007

(54) Module apparatus and method for controlling auto on/off of clock for saving power

(75) Inventor: Man-Suk Park, Seoul (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics Co., Ltd.

(21) Appl. No.: 11/396,585

(22) Filed: Apr. 4, 2006

(30) Foreign Application Priority Data
Sep. 23, 2005 (KR) 2005-0088949

(51) Int. Cl. G11C 8/00

(52) U.S. Cl. 365/233

(57) ABSTRACT

A module apparatus and method for saving power by automatically controlling an ON/OFF state of a clock is provided. The module apparatus comprises a core performing special functions and storing operation information, and a clock controller applying or not applying an external clock input according to the operation information transmitted from the core. Accordingly, the clock is applied only during operation of the module apparatus, thereby saving power and reducing heat generation.

### PRIORITY

This application claims the benefit under 35 U.S.C. § 119(a) of a Korean patent application No. 2005-88949, filed Sep. 23, 2005, in the Korean Intellectual Property Office, the entire contents of which are hereby incorporated by reference.

### BACKGROUND OF THE INVENTION

1. Field of the Invention

The present invention relates to a module apparatus and method for automatically controlling an ON/OFF state of a clock thereof. More particularly, the present invention relates to a module apparatus and method for an application specific integrated circuit (ASIC) operated on the basis of a clock and capable of automatically controlling an ON/OFF state of the clock in order to save power.

2. Description of the Related Art

Generally, an application specific integrated circuit (ASIC) operates based on a clock and consumes power corresponding to the clock. Likewise, a module apparatus equipped in an ASIC operates based on the clock and consumes power corresponding to the clock.

The module apparatus is a master device having a bus access right, and is connected parallel to one common bus. The module apparatus accesses or requests data from another master or a slave unit using the bus, and compresses, recovers and converts the data to a signal.

FIG. 1 is a perspective view of a conventional ASIC having a module apparatus.

Referring to FIG. 1, a conventional ASIC comprises a central processing unit (CPU) 110, a control/data bus 115, an arbiter 120, and a plurality of module apparatuses 130, 130-1, 130-2, . . . , 130-n. An external clock is input to the ASIC apparatus collectively and then evenly to the respective component elements.

The CPU 110 controls the module apparatuses 130, 130-1, 130-2, . . . , 130-n using the control/data bus 115 based on the external clock input. The arbiter 120 controls the control/data bus 115 based on the clock. The module apparatuses 130, 130-1, 130-2, . . . , 130-n perform their particular functions based on the clock, such as access, compression and recovery, and signal conversion with respect to data.

FIG. 2 is a block diagram of a conventional module apparatus. Referring to FIG. 2, the module apparatus 130 in a conventional ASIC comprises a special function register (SFR) 132 and a core 134. The other module apparatuses 130-1, 130-2, . . . , 130-n, shown in FIG. 1, are structured in the same manner.

The SFR 132 stores information input by the CPU 110 through the bus 115 based on the clock. The core 134 performs a corresponding function of the module apparatus 130 according to the information stored in the SFR 132 based on the clock.

As described above, in a conventional ASIC, since the clock signal is provided to all module apparatuses, even when not in use, a module apparatus that is not in operation consumes a certain amount of power, thereby causing waste of power.

### SUMMARY OF THE INVENTION

Aspects of exemplary embodiments of the present invention address at least the above problems and/or disadvantages and provide at least the advantages described below. Accordingly, an aspect of an exemplary embodiment of the present invention provides a module apparatus and method capable of automatically controlling an ON/OFF state of the clock for saving power by turning the clock ON only during operation of the module apparatus and turning the clock OFF when the module apparatus is not in operation.

In order to achieve the above-described aspects of the exemplary embodiments of the present invention, a module apparatus comprising a core for performing special functions and storing operation information is provided. A clock controller for selectively applying an external clock input according to the operation information transmitted from the core is also provided.

In an exemplary embodiment, the operation information comprises information of an operation starting time and an operation ending time of the core, and the clock controller applies the external clock input to the core during the operation starting time until the operation ending time.

In an exemplary embodiment, the operation starting time information comprises logic levels of a starting signal and an ending signal at the operation starting time, and the operation ending time information comprises logic levels of a starting signal and an ending signal at the operation ending time.

In an exemplary embodiment, the core transmits to the clock controller a logic level 1 as the starting signal and a logic level 0 as the ending signal at the operation starting time, and transmits a logic level 0 as the starting signal and a logic level 1 as the ending signal at the operation ending time.

In an exemplary embodiment, the clock controller comprises an inverter for inversely converting the ending signal transmitted from the core, a first AND gate logically multiplies the ending signal inversely converted by the inverter by the starting signal transmitted from the core, and a second AND gate logically multiplies a signal logically multiplied by the first AND gate by the external clock input.

According to another aspect of an exemplary embodiment of the present invention, a module apparatus is provided comprising a core performing special functions, a special function register (SFR) storing the operation information of the core, and a clock controller applying, or not applying, an external clock input to the core according to the operation information stored in the SRF.

A method for automatically turning on and off a clock in a module apparatus, according to an aspect of an exemplary embodiment of the present invention, comprises transmitting operation information from the core to the clock controller, and applying, or not applying, an external clock input according to the transmitted operation information of the core.

In an exemplary embodiment, the operation information comprises operation starting time information and operation ending time information of the core, and the applying step comprises applying the external clock input to the core during the operation starting time until the operation ending time of the core.

In an exemplary embodiment, the operation starting time information comprises a logic level of a starting signal and an ending signal of the operation starting time, and the operation ending time information comprises a logic level of a starting signal and an ending signal of at the operation ending time.

In an exemplary implementation, in the step of transmitting operation information to the clock controller, a logic level 1 starting signal and a logic level 0 ending signal are transmitted at the operation starting time, and a logic level 0 starting signal and a logic level 1 ending signal are transmitted at the operation ending time.

The applying step comprises inversely converting the ending signal transmitted from the core, logically multiplying the inversely converted ending signal by the starting signal transmitted from the core, and logically multiplying the logically-multiplied signal by the external clock input.

In an exemplary embodiment, an application specific integrated circuit (ASIC) may comprise a module apparatus maintaining a clock in an ON state from an operation starting time to an operation ending time of the module apparatus.

### BRIEF DESCRIPTION OF THE DRAWING FIGURES

The above and other aspects, exemplary features, and advantages of the present invention will become more apparent from the following detailed description of certain exemplary embodiments thereof with reference to the accompanying drawing figures, in which:

FIG. 1 is a view showing a conventional application specific integrated circuit (ASIC) having a module apparatus;

FIG. 2 is a block diagram of a conventional module apparatus;

FIG. 3 is a block diagram of a module apparatus according to an exemplary embodiment of the present invention;

FIG. 4 is a block diagram of a clock controller provided to the module apparatus according to an exemplary embodiment of the present invention;

FIG. 5 is a timing diagram of the module apparatus according to an exemplary embodiment of the present invention; and

FIG. 6 is a flowchart for explaining a method for automatically controlling an ON/OFF state of a clock of the module apparatus, according to an exemplary embodiment of the present invention.

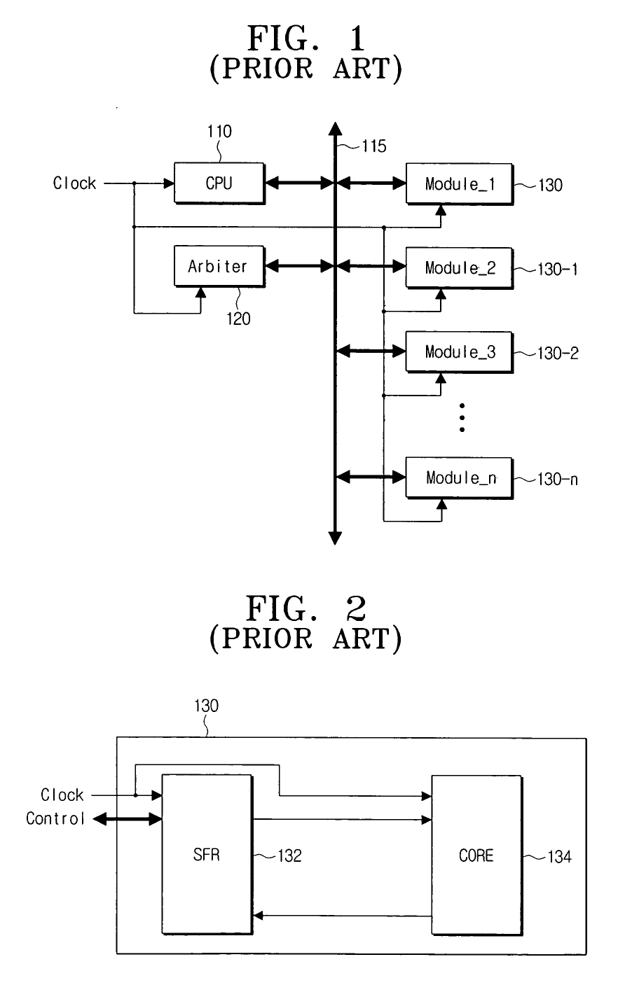

Throughout the drawings, like reference numbers should be understood to refer to like elements, features, and structures.

### DETAILED DESCRIPTION OF EXEMPLARY EMBODIMENTS

The matters exemplified in this description are provided to assist in a comprehensive understanding of various exemplary embodiments of the present invention disclosed with reference to the accompanying figures. Accordingly, those of ordinary skill in the art will recognize that various changes and modifications of the exemplary embodiments described herein can be made without departing from the scope and spirit of the claimed invention. Descriptions of well-known functions and constructions are omitted for clarity and conciseness.

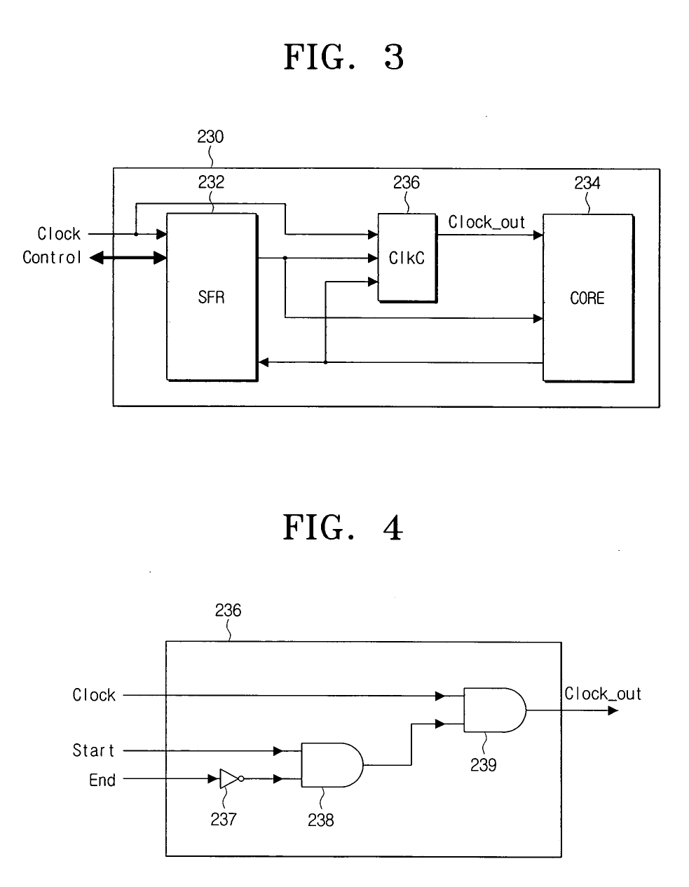

FIG. 3 is a block diagram of a module apparatus according to an exemplary embodiment of the present invention.

A module apparatus 230 is mounted in an application specific integrated circuit (ASIC) and performs access, compression and recovery, and signal conversion with respect to data based on an external clock input.

During operation of the module apparatus 230, the external clock input is automatically turned on. When the module apparatus 230 is not operating, the clock input is turned off automatically.

Referring to FIG. 3, the module apparatus 230 comprises a special function register (SFR) 232, a core 234, and a clock controller 236.

The SFR 232 stores information for operating the module apparatus 230 which is input through a bus. Additionally, the SFR 232 stores operation information which is information on a time for starting operation of the core 234 (hereinafter, referred to as ‘operation starting time’) and a time for ending the operation of the core 234 (hereinafter, referred to as ‘operation ending time’).

The core 234 performs the functions of the module apparatus 230 in accordance with the information stored in the SFR 232. For example, the core 234 performs the functions of the module apparatus 230 based on the clock input from the clock controller 236 at the operation starting time. The core 234 is aware of the operation information and may transmit the operation information to the clock controller 236.

The clock controller 236 provides the external clock input to the core 234 based on the operation information stored in the SFR 232 or the operation information transmitted from the core 234. For example, the clock controller 236 reads the operation information stored in the SFR 232, or by receiving the operation information from the core 234, turns on the clock input from the external clock at the operation starting time of the core 234. In other words, the clock controller 236 provides the external clock input to the core 234.

On the other hand, at the operation ending time of the core 234, the clock controller 236 turns the external clock input OFF, for example, by not providing the external clock input to the core 234.

FIG. 4 is a block diagram of the clock controller provided to the module apparatus according to an exemplary embodiment of the present invention.

The clock controller 236 automatically turns ON and OFF the external clock input based on the operation information transmitted from the SFR 232 or the core 234.

Referring to FIG. 4, the clock controller 236 comprises an inverter 237, a first AND gate 238, and a second AND gate 239.

At the core 234 operation starting time, the clock controller 236 reads the operation information stored in the SFR 232. Alternatively, the core 234 may apply the operation information to the clock controller 236. In particular, the operation information represents the state of a starting signal and an ending signal of the operation starting time, that is, the operation information comprises a logic level. At the operation starting time, the starting signal has a logic level 1 and the ending signal a logic level 0 as operation starting time information. Inverter 237 is connected to an input end of the ending signal and converts inversely the logic level 0 to a logic level 1.

The first AND gate 238 logically-multiplies a logic level 1 applied as the starting signal by the logic level 1 inversely converted by the inverter 237. As a result of the logical multiplication of the logic levels 1 and 1, the first AND gate 238 outputs a logic level 1, which comprises the starting signal.

The second AND gate 239 logically-multiplies the external clock input by the logic level 1 supplied from the first AND gate 238. Therefore, the output of the second AND gate 239 follows the clock signal.

At the core 234 operation ending time, on the other hand, the clock controller 236 reads the operation information stored in the SFR 232. Alternatively, the core 234 may apply the operation ending information to the clock controller 236. For example, the operation ending information represents the logic levels of a starting signal and an ending signal of the operation ending time. At the operation ending time, the starting signal has a logic level 0 and an ending signal a logic level 1 as operation ending time information.

In an exemplary implementation, inverter 237 is connected to the input end of the ending signal and inverts the logic level 1 to a logic level 0.

The first AND gate 238 logically-multiplies a logic level 0 applied as the starting signal by the logic level 0 inversely converted by the inverter 237. As a result of the logical multiplication of the logic levels 0 and 0, the first AND gate 238 outputs a logic level 0, which comprises the ending signal.

The second AND gate 239 logically-multiplies the external clock input by the logic level 0 supplied from the first AND gate 238. As a result of logical multiplication of the clock signal by the logic level 0, the second AND gate 239 outputs a logic level 0, in other words, the output of the second AND gate 239 does not follow the clock signal.

Thus, the clock controller 236 supplies the clock signal to the core 234 only when the core 234 is in operation, thereby reducing power consumption.

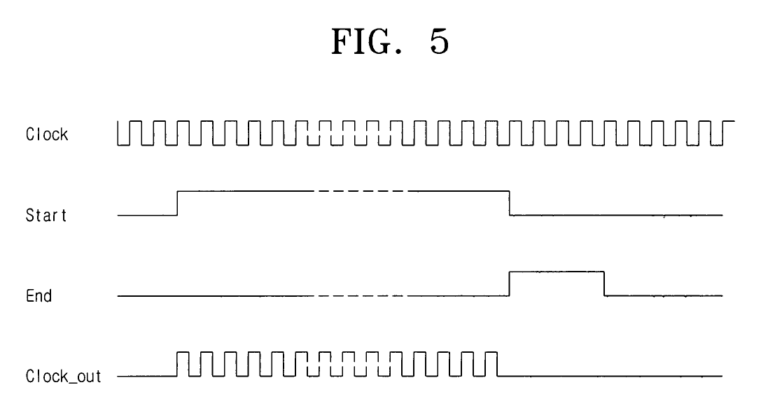

FIG. 5 is a timing diagram of the module apparatus according to an exemplary embodiment of the present invention.

As shown in FIG. 5, the clock signal is continuously applied to the module apparatus 230 from an external source. The starting signal is applied to the clock controller 236 from the SFR 232 or the core 234 at the operation starting time. The starting signal is continuously applied to the clock controller 236 while the core 234 is in operation. The ending signal is applied to the clock controller 236 from the SRF 232 or the core 234 at the operation ending time of the core 234. A clock-out signal is applied to the core 234 by the clock controller 236. The clock controller 236 applies the clock signal to the core 234 only while the starting signal is being applied. From the time of applying the ending signal, the clock controller 236 does not apply the clock to the core 234.

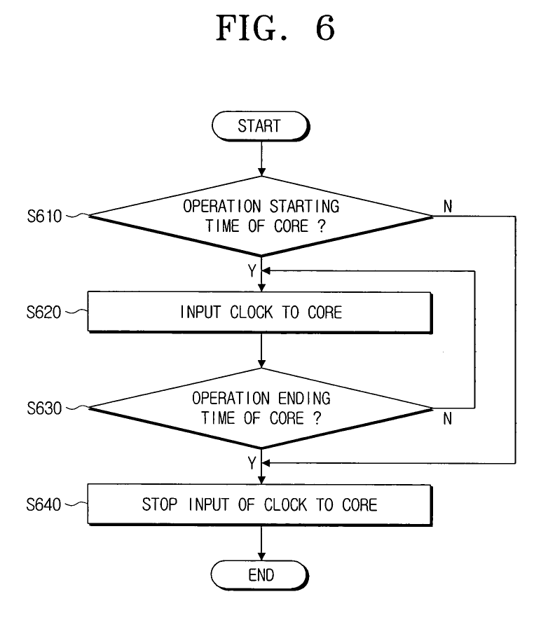

FIG. 6 is a flowchart for explaining a method for automatically controlling an ON/OFF state of a clock of the module apparatus according to an exemplary embodiment of the present invention.

Referring to FIG. 6, the clock controller 236 determines whether it is time for starting operation of the core 234, step S610. According to the operation information supplied from the SFR 232 or the core 234, the clock controller 236 determines the operation starting time for the core 234.

When it is determined to be the operation starting time, the clock controller 236 supplies the external clock input to the core 234, step S620.

The clock controller 236 determines whether it is time for ending the operation of the core 234, step S630. According to the operation information supplied from the SFR 232 or the core 234, the clock controller 236 determines the operation ending time for the core 234, and the input of the clock signal is stopped, step S640.

As can be appreciated from the above description, according to exemplary embodiments of the present invention, the clock signal can be applied only when the module apparatus is in operation and, accordingly, power can be saved. Additionally, heat generation can be reduced.

While the present invention has been particularly shown and described with reference to certain exemplary embodiments thereof, it will be understood by those of ordinary skill in the art that various changes in form and detail may be made therein without departing from the spirit and scope of the present invention as defined by the appended claims and equivalents thereof.

What is claimed is:

1. A module apparatus comprising:
a core for performing special functions and storing operation information; and
a clock controller for selectively applying an external clock input according to the operation information transmitted from the core.

2. The module apparatus of claim 1, wherein the operation information comprises information of an operation starting time and an operation ending time of the core, and wherein the clock controller applies the external clock input to the core from the operation starting time to the operation ending time.

3. The module apparatus of claim 2, wherein the information of the operation starting time comprises logic levels of a starting signal and an ending signal at the operation starting time, and the information of the operation ending time information comprises logic levels of a starting signal and an ending signal at the operation ending time.

4. The module apparatus of claim 3, wherein the core transmits to the clock controller a logic level 1 starting signal and a logic level 0 ending signal at the operation starting time, and transmits a logic level 0 starting signal and a logic level 1 ending signal at the operation ending time.

5. The module apparatus of claim 3, wherein the clock controller comprises:
an inverter for inverting the ending signal transmitted from the core;
a first AND gate logically-multiplying the ending signal inversely converted by the inverter by the starting signal transmitted from the core; and
a second AND gate for logically-multiplying a signal logically-multiplied by the first AND gate by the external clock input.

6. A module apparatus comprising:
a core for performing special functions;
a special function register (SFR) for storing operation information of the core; and
a clock controller for selectively applying an external clock input to the core according to the operation information stored in the SFR.

7. A method for automatically turning ON and OFF a clock signal in a module apparatus, the method comprising:
transmitting operation information of a core; and
selectively applying an external clock input according to the transmitted core operation information.

8. The method of claim 7, wherein the operation information comprises operation starting time information and operation ending time information of the core, and wherein the applying step comprises applying the external clock input to the core from the operation starting time until the operation ending time of the core.

9. The method of claim 8, wherein the operation starting time information comprises a logic level of a starting signal and an ending signal of the operation starting time, and the operation ending time information comprises a logic level of a starting signal and an ending signal of the operation ending time.

10. The method of claim 7, wherein, in the step of transmitting the core operation information, a logic level 1 starting signal and a logic level 0 ending signal 0 and are transmitted at the operation starting time, and a logic level 0 starting signal and a logic level 1 ending signal and are transmitted at the operation ending time.

11. The method of claim 9, wherein the applying step further comprises:
inverting the transmitted ending signal;
logically-multiplying the inversely converted ending signal by the transmitted starting signal; and
logically-multiplying the logically-multiplied signal by the external clock input.

12. An application specific integrated circuit (ASIC) comprising a module apparatus maintaining a clock in an ON state from an operation starting time to an operation ending time of the module apparatus.
